(19) United States
(12) Patent Application Publication
(10) Pub. No.: US 2015/0079481 A1
(43) Pub. Date: Mar. 19, 2015

(54) SOLID STATE ELECTROLYTE AND BARRIER ON LITHIUM METAL AND ITS METHODS

(71) Applicant: APPLIED MATERIALS, INC., Santa Clara, CA (US)

(72) Inventors: Lizhong SUN, San Jose, CA (US); Chong JIANG, Cupertino, CA (US); Byung-Sung Leo KWAK, Portland, OR (US); Joseph G. GORDON, II, San Jose, CA (US)

(21) Appl. No.: 14/146,446

(22) Filed: Jan. 2, 2014

Related U.S. Application Data
(63) Continuation-in-part of application No. 13/523,790, filed on Jun. 14, 2012.
(60) Provisional application No. 61/498,480, filed on Jun. 17, 2011.

(51) Int. Cl. C23C 14/34; H01M 6/40

(52) U.S. Cl. CPC C23C 14/3414; H01M 6/40
USPC 429/322; 204/192.22; 204/298.13

(57) ABSTRACT

A method of fabricating an electrochemical device comprising a lithium metal electrode, may comprise: providing a substrate with a lithium metal electrode on the surface thereof; depositing a first layer of dielectric material on the lithium metal electrode, the depositing the first layer being sputtering Li₃PO₄ in an argon ambient; after the depositing the first layer, inducing and maintaining a nitrogen plasma over the first layer of dielectric material to provide ion bombardment of the first layer for incorporation of nitrogen therein; and after the depositing, the inducing and the maintaining, depositing a second layer of dielectric material on the ion bombarded first layer of dielectric material, the depositing the second layer being sputtering Li₃PO₄ in a nitrogen-containing ambient. Electrochemical devices may comprise a barrier layer between the lithium metal electrode and the LiPON electrolyte. Tools configured for fabricating the electrochemical devices comprising lithium metal electrodes are also described.

### CROSS-REFERENCE TO RELATED APPLICATIONS

This application is a continuation-in-part of U.S. patent application Ser. No. 13/523,790, filed Jun. 14, 2012, which claims the benefit of U.S. Provisional Application Ser. No. 61/498,480 filed Jun. 17, 2011, which are incorporated herein by reference in their entirety.

### FIELD

Embodiments of the present disclosure relate generally to thin film deposition and more specifically to methods for depositing a solid state electrolyte layer such as LiPON onto lithium metal, and related devices and deposition apparatus.

### BACKGROUND

FIG. 1 shows a cross-sectional representation of a typical thin film battery (TFB). The TFB device structure 100 with anode current collector 103 and cathode current collector 102 are formed on a substrate 101, followed by cathode 104, electrolyte 105 and anode 106; although the device may be fabricated with the cathode, electrolyte and anode in reverse order. Furthermore, the cathode current collector (CCC) and anode current collector (ACC) may be deposited separately. For example, the CCC may be deposited before the cathode and the ACC may be deposited after the electrolyte. The device may be covered by an encapsulation layer 107 to protect the environmentally sensitive layers from oxidizing agents. See, for example, N.J. Dudney, Materials Science and Engineering B 1 16, (2005) 245-249. Note that the component layers are not drawn to scale in the TFB device shown in FIG. 1.

In a typical TFB device structure, such as shown in FIG. 1, the electrolyte—a dielectric material such as Lithium Phosporous Oxynitride (LiPON)—is sandwiched between two electrodes—the anode and cathode. LiPON is a chemically stable solid state electrolyte with a wide working voltage range (up to 5.5 V) and relatively high ionic conductivity (1-2 μS/cm). Solid state batteries, especially the thin film version, contain LiPON as an electrolyte as such cells are capable of more than 20,000 charge/discharge cycles with only 0.001% capacity loss/cycle. The conventional method used to deposit LiPON is physical vapor deposition (PVD) radio frequency (RF) sputtering of a Li₃PO₄ target in a N₂ ambient.

In solid state battery structures, where Li is involved as an anode material, the reactivity of the Li presents significant challenges in creating the battery. Such challenging situations arise when the Li anode needs to be protected in a conventional order of fabricating the battery, for example in a thin film (vacuum deposited) solid state battery, where on a substrate, cathode current collector, cathode, electrolyte, anode are formed sequentially in this approximate order, leaving the top Li anode to be coated in some way to protect it from reactions with ambient atmosphere. Another such situation arises when an “inverted” battery structure is considered—Li anode first, followed by the electrolyte, and the cathode. This structure can be either vacuum deposited or by non-vacuum methods (slot die, printing, etc.). The challenge, in the case of the inverted battery structure, arises when the electrolyte layer, such as LiPON, needs to be deposited on the Li metal surface.

Clearly, there is a need for electrochemical device structures, deposition processes and fabrication apparatus which can accommodate a LiPON dielectric thin film deposition on a lithium metal surface.

### SUMMARY OF THE INVENTION

Present disclosures include methods of depositing a solid state electrolyte layer such as LiPON, which is an electrolyte material used in high energy density solid state batteries, onto lithium metal. In order to avoid nitrogen plasma contact with lithium metal during the LiPON deposition, a very thin (10 nm-100 nm) Li₃PO₄ layer, which is also a solid state electrolyte, though of lower ionic conductivity, is first deposited on the lithium metal in a 100% Ar atmosphere using a Li₃PO₄ target. The Li₃PO₄ film deposition is then followed by a nitrogen plasma treatment to improve the ionic conductivity of the Li₃PO₄ film and then LiPON deposition to a desired thickness in a pure nitrogen atmosphere with the same target.

According to some embodiments of the disclosure, a method of fabricating an electrochemical device comprising a lithium metal electrode may comprise: providing a substrate with a lithium metal electrode on the surface thereof; depositing a first layer of dielectric material on the lithium metal electrode, the depositing the first layer of dielectric material being sputtering Li₃PO₄ in an argon ambient; after the depositing the first layer of dielectric material, inducing and maintaining a nitrogen plasma over the first layer of dielectric material to provide ion bombardment of the first layer of dielectric material for incorporation of nitrogen therein; and after the depositing, the inducing and the maintaining, depositing a second layer of dielectric material on the ion bombarded first layer of dielectric material, the depositing the second layer of dielectric material being sputtering Li₃PO₄ in a nitrogen-containing ambient.

According to further embodiments of the present disclosure, an electrochemical device may comprise: a substrate with a lithium metal electrode on the surface thereof; an ion bombarded first layer of dielectric material on the lithium metal electrode, the ion bombarded first layer of dielectric material being a layer of material formed by sputtering a Li₃PO₄ target in an argon ambient followed by plasma treatment in a nitrogen containing ambient; a second layer of dielectric material on the ion bombarded first layer of dielectric material, the second layer of dielectric material being formed by sputtering Li₃PO₄ in a nitrogen-containing ambient; and a second electrode on the second layer of dielectric material.

Furthermore, this disclosure provides tools configured for carrying out the methods of the present disclosure as described herein.

### BRIEF DESCRIPTION OF THE DRAWINGS

These and other aspects and features of the present disclosure will become apparent to those ordinarily skilled in the art upon review of the following description of specific embodiments of the disclosure in conjunction with the accompanying figures, wherein:

FIG. 1 is a cross-sectional representation of a prior art thin film battery;

FIG. 2 is a schematic representation of a deposition system, according to some embodiments of the present disclosure;

FIG. 3 is a flow chart for deposition of a solid state electrolyte and a barrier layer thin film on a lithium metal electrode of an electrochemical device, according to some embodiments of the present disclosure;

FIG. 4 is a cross-sectional representation of a vertical stack thin film battery, according to some embodiments of the present disclosure;

FIG. 5 is a schematic illustration of a thin film deposition cluster tool, according to some embodiments of the present disclosure;

FIG. 6 is a representation of a thin film deposition system with multiple in-line tools, according to some embodiments of the present disclosure; and

FIG. 7 is a representation of an in-line deposition tool, according to some embodiments of the present disclosure.

### DETAILED DESCRIPTION

Embodiments of the present disclosure will now be described in detail with reference to the drawings, which are provided as illustrative examples of the disclosure so as to enable those skilled in the art to practice the disclosure. The drawings provided herein include representations of devices and device process flows which are not drawn to scale. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Deposition of a LiPON layer on a lithium metal surface is desired in various electrochemical devices, including a TFB. The conventional method used to deposit LiPON is physical vapor deposition (PVD) radio frequency (RF) sputtering of a Li₃PO₄ target in a nitrogen ambient. The problem is that the sputtering nitrogen plasma causes the following reaction: 6Li+N₂→2 Li₃N, once the substrate (lithium metal) meets the nitrogen plasma before the LiPON can cover it up. The product, L₃N, has a very small voltage range (˜0.4 V) vs. Li reference electrode. While formation of Li₃N in itself is not an issue (Li₃N is a Li ion conductor), we find that the reaction is not self-limiting but continues to eat up the lithium metal, the charge carrier for the battery, leaving only the charge carriers in the cathode for the battery operation. Here, we are assuming that the cathode is deposited in a lithiated, fully discharged state, from which the cycling carriers are drawn. Such cells without a reservoir of additional Li ion charge carriers typically show lower cyclability and capacity retention as the loss of charge carriers, Li, by various mechanisms over the life of the battery, directly affects the capacity and the cycle life. Therefore, a viable method of depositing LiPON onto lithium metal is key in fabricating high performance functional batteries, of the types described above.

The forming of such a stable stack including LiPON material deposited on Li will also provide opportunities to create cell stacks of hybrid nature, such as using very thick non-vacuum deposited cathode layers with liquid electrolyte that can lead to much higher capacity, energy density and lower cost. Lower cost can result from the non-vacuum method of forming the thick cathode. For example, a “laminated dual-substrate structure” where one side is substrate/ACC/Li/Barrier Layer/LiPON and the other one is substrate/CCC/cathode/liquid electrolyte.

The thin Li₃PO₄ barrier layer, sputtered in Ar only, effectively prevents lithium metal from contacting nitrogen plasma during the subsequent step of forming the LiPON. This effectively avoids the reaction between lithium metal and nitrogen plasma described above when the LiPON layer is actually deposited. In addition, the whole process can take place in the same sputtering chamber in a continuous manner with no air break, no solution processing, and thus, no additional cost. In the case of single wafer, batch processing tools like the Applied Materials Endura™ may be used. In an “inline” tool, where the substrates move continuously in front of multiple adjacent targets, one can use the first target as the initial barrier coating step, while the rest of the subsequent targets can be used to build up the necessary LiPON layer, again done in a single tool. To compensate for the lower ionic conductivity of the initial barrier layer, the nitrogen plasma treatment is incorporated after the Li₃PO₄ layer is first deposited. This will not only increase the ionic conductivity, but also the pinhole remediation effect of the plasma treatment will allow better protection during the subsequent LiPON deposition step. Clearly, there are multiple ways of treating the layer with plasma after the Li₃PO₄ deposition in Ar ambient is performed. Note that Ar plasma may provide pinhole remediation, while nitrogen plasma may provide both ionic conductivity and pinhole remediation. Thus, one can sputter using an Ar plasma followed by a treatment of the sputtered film by a nitrogen plasma.

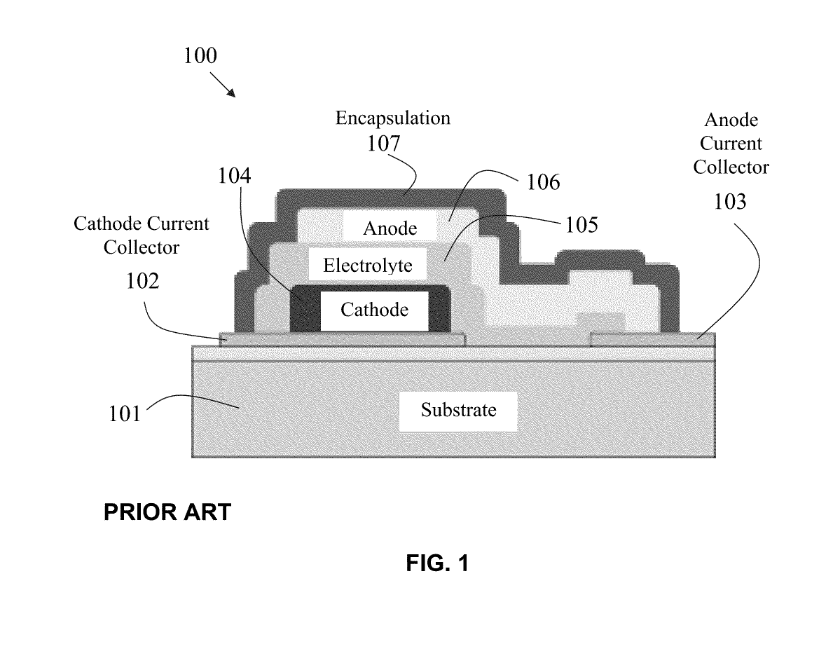

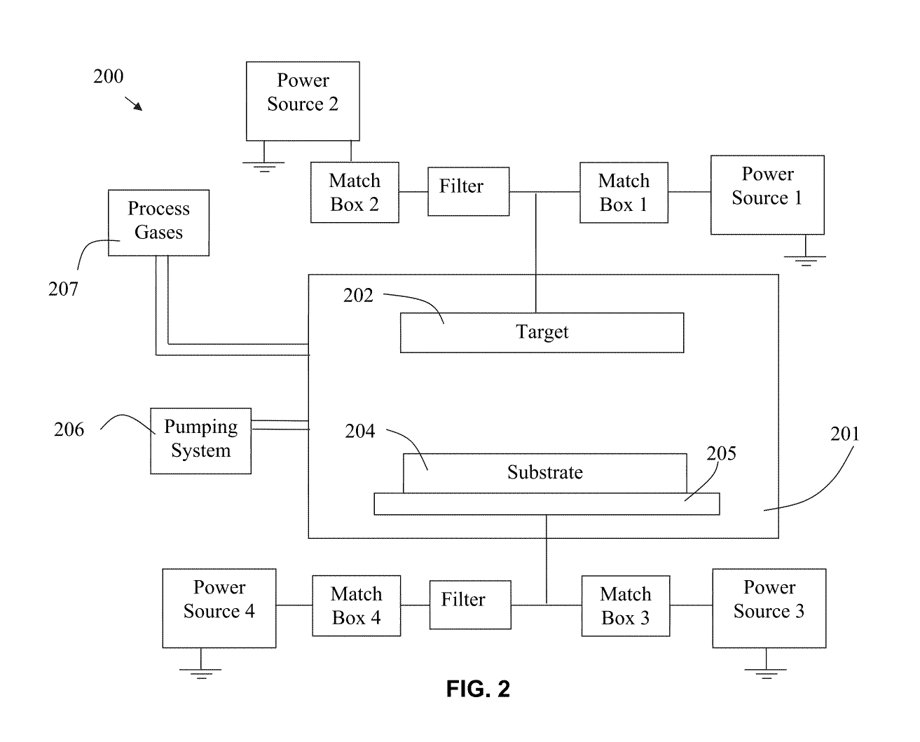

FIG. 2 shows a schematic representation of an example of a deposition tool 200 configured for deposition methods according to the present disclosure. The deposition tool 200 includes a vacuum chamber 201, a sputter target 202, a substrate 204 and a substrate pedestal 205. For LiPON deposition the target 202 may be Li₃PO₄ and a suitable substrate 204 may be silicon, silicon nitride on Si, glass, PET (polyethylene terephthalate), mica, metal foils such as copper, etc., with current collector(s) and electrode layer(s) already deposited and patterned, if necessary. See FIGS. 1 & 4, for example. The chamber 201 has a vacuum pump system 206 and a process gas delivery system 207. Multiple power sources are connected to the target. Each target power source has a matching network for handling radio frequency (RF) power supplies. A filter is used to enable use of two power sources operating at different frequencies, where the filter acts to protect the target power supply operating at the lower frequency from damage due to higher frequencies. Similarly, multiple power sources are connected to the substrate. Each power source connected to the substrate has a matching network for handling radio frequency (RF) power supplies. A filter is used to enable use of two power sources operating at different frequencies, where the filter acts to protect the power supply connected to the substrate operating at the lower frequency from damage due to higher frequencies.

Depending on the type of deposition and plasma pinhole reduction techniques used, one or more of the power sources connected to the substrate can be a DC source, a pulsed DC (pDC) source, an RF source, etc. Similarly, one or more of the target power sources can be a DC source, a pDC source, an RF source, etc. Some examples of configurations and uses of the power sources (PS) are provided below in Table 1. Furthermore, the concepts and configurations of the combinatorial power supplies described in U.S. Patent Application Publication No. 2009/0288943 to Kwak et al., incorporated herein by reference in its entirety, may be used in the deposition of the thin films according to some embodiments of the present disclosure; for example, combinations of sources other than RF sources may be effective in providing reduced pinhole density in deposited films. In addition, the substrate may be heated during deposition.

TABLE 1

| | Power | Power | Power | Power |
|---|---|---|---|---|
| Process | Source 1 | Source 2 | Source 3 | Source 4 |
| Sputter | RF source | RF source | DC source or | RF source |
| Deposition | at a first | at a second | pDC source | |
| #1 | frequency | frequency | | |
| Plasma | | | | RF source |
| Pinhole | | | | |
| Filling #1 | | | | |
| Sputter | RF source | RF source | RF source at | RF source |
| Deposition | at a first | at a second | a different | |
| #2 | frequency | frequency | frequency* | |
| Plasma | | | | RF source |
| Pinhole | | | | |
| Filling #2 | | | | |

*A frequency of less than 1 MHz may be used.

Table 1 provides example configurations of power sources for sputter deposition and plasma pinhole filling processes according to some embodiments of the present disclosure. Sputter depositions #1 and #2 may be used to sputter deposit a material such as LiPON or Li₃PO₄ using a Li₃PO₄ target in a nitrogen or argon ambient (in the case of the latter, a subsequent nitrogen plasma treatment, which may also be part of a pinhole filling process, may be used to incorporate the nitrogen needed to improve the lithium ion ionic conductivity of the Li₃PO₄).

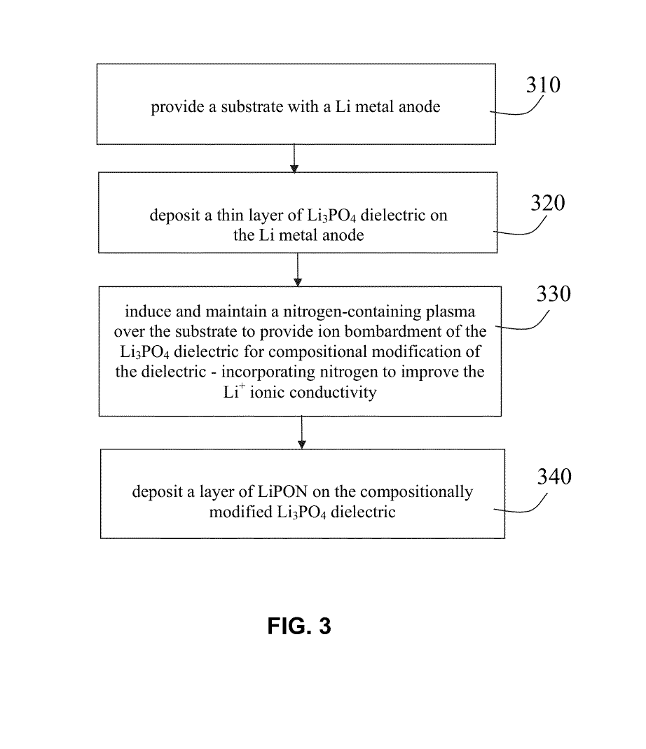

According to some embodiments of the present disclosure LiPON deposition on a Li metal electrode may proceed according to the general process flow of FIG. 3. The process flow may include: providing a substrate with a lithium metal anode (310); depositing a thin layer of Li₃PO₄ dielectric on the lithium metal anode (320); inducing and maintaining a nitrogen-containing plasma over the substrate to provide ion bombardment of the deposited layer of dielectric for compositional modification of the dielectric-incorporating nitrogen to improve the Li⁺ ionic conductivity (330); and depositing a layer of LiPON on the compositionally modified Li₃PO₄ dielectric (340). Herein, the thin layer of dielectric refers to a layer of Li₃PO₄ dielectric with a thickness of a few nanometers to a few hundred nanometers, and in embodiments a layer of thickness 10 nm to 100 nm, and further embodiments a layer of thickness 20 nm to 60 nm.

More generally, according to embodiments of the disclosure, the following method may be used to make electrochemical devices with lithium metal electrodes. First, a substrate with a lithium metal electrode thereon is provided; the substrate may be glass, silicon, copper, etc. Second, a first layer of dielectric material is deposited on the lithium metal electrode by sputtering Li₃PO₄ in an argon ambient. Third, the RF target power source is turned off, and the chamber gas is changed to provide a nitrogen-containing ambient, or the substrate is moved to a different chamber with a nitrogen-containing ambient. Fourth, RF is applied directly to the substrate using an RF substrate power source to generate a localized plasma adjacent to the substrate surface—this plasma generates energetic ions with sufficient energy to enable incorporation of nitrogen into the first layer to improve the Li⁺ ionic conductivity. Fifth, the plasma treatment is finished and then a second layer of dielectric material is deposited over the ion bombarded first layer by sputter deposition from a Li₃PO₄ source in a nitrogen ambient. Note that the nitrogen plasma treatment of the first layer may also be effective in eliminating any pinholes that may have formed in the first layer. Furthermore, note that the nitrogen plasma treatment may be done in a separate chamber to the deposition of the first layer, and furthermore that the deposition of the second layer may be done in the same chamber as the nitrogen plasma treatment, or in a different chamber.

The inventors noted that deposition of a thin film by sputtering a Li₃PO₄ target with argon appears to also improve the efficacy of pinhole reduction in the thin film, when compared with deposition of a thin film using sputter deposition from a Li₃PO₄ target in a nitrogen ambient. This may be because nitrogen poisons the Li₃PO₄ target which can result in particle generation by the target and these particles can result in pinholes in the deposited films, whereas argon does not poison the target, and thus leads to reduced particle shedding and reduced pinhole formation. Furthermore, films formed by sputtering Li₃PO₄ using argon ambient and then treated with nitrogen plasma for pinhole removal showed an improved ionic conductivity over films sputter deposited using nitrogen ambient but without a nitrogen plasma post deposition treatment. The improved ionic conductivity may be due to more effective incorporation of nitrogen into the LiPON film during the nitrogen plasma treatment. The LiPON material with nitrogen incorporation may be represented by LiₐPO_{b}N_{c} wherein 2.5≦a≦3.5; 3.7≦b≦4.2; and 0.05≦c≦0.3. To a certain extent, the higher the nitrogen content the higher the ionic conductivity. Note that the efficiency of the nitrogen plasma process for pinhole removal and improved ionic conductivity may be increased by controlling the substrate temperature. For LiPON deposition, higher temperature improves nitrogen incorporation, although the temperature should not be too high otherwise the film may crystallize—controlling the substrate temperature to a temperature within the range of room temperature to 300° C. may provide a more efficient process for LiPON thin film deposition. Furthermore, it is expected that similar results may be obtained using other gases, such as xenon, substituted for argon, although the high cost of gases such as xenon compared with argon may limit their use.

Table 2 below shows a sample plasma recipe for Li₃PO₄ deposition and nitrogen plasma treatment, according to some embodiments of the present disclosure carried out on an Applied Materials 200 mm Endura™ Standard Physical Vapor Deposition (PVD) chamber.

TABLE 2

| | Ar | N₂ | RF Power | Substrate |
|---|---|---|---|---|
| | Pressure | Pressure | (Watts) for | Temperature |
| Variation | (mTorr) | (mTorr) | 200 mm Tool† | (° C.) |
| Li₃PO₄ | 2-1000 | 0 | 200-5000 | RT to 300 |
| Sputter | | | | |
| Deposition | | | | |
| Plasma | 0 | 2-1000 | 0-1000 | RT to 300 |
| Pinhole | | | | |
| Filling and | | | | |
| Ionic | | | | |
| Conductivity | | | | |
| Improvement | | | | |

†Upper limit of power is due to the limit of the power supply used and does not represent the upper limit for the process as determined by target area and power density limit of the target material. It is expected that the power may be increased up to the point at which target cracking begins.

Table 2 provides an example of process conditions for sputtering Li₃PO₄ to form thin films, followed by plasma treatment to improve the Li⁺ ionic conductivity, and also reduced pinhole density. This is only one example of the many varied process conditions that may be used. Note that the process scales to larger area tools. For example, an in-line tool with a 1400 mm×190 mm rectangular Li₃PO₄ target has been operated at 10 kW. A large in-line target might operate with RF power that has an upper limit determined by the target area and the power density limit of the target material.

Furthermore, the process conditions may be varied from those described above. For example, the deposition temperature may be higher, the source power may be pDC, and the sputter gas may be an Ar/N₂ mixture. Those skilled in the art will appreciate after reading the present disclosure that adjustments of these parameters may be made to improve the uniformity of deposited films, surface roughness, layer density, etc., if desired.

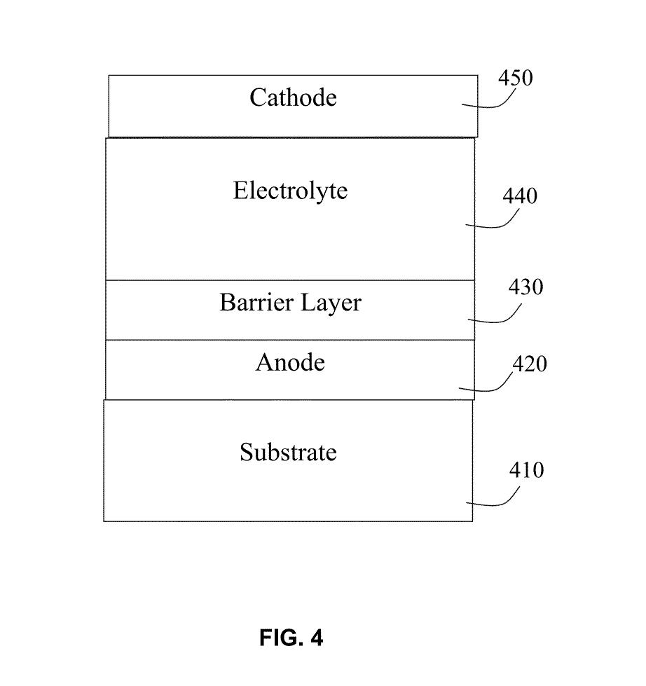

FIG. 4 shows an example of an electrochemical device with a vertical stack fabricated according to methods of the present disclosure; the methods of the present disclosure may also be used to fabricate devices with the general configuration of FIG. 1, although the present disclosure includes a barrier layer between the lithium metal anode and the LiPON electrolyte. In FIG. 4, the vertical stack comprises: a substrate 410, a lithium metal anode 420, a barrier layer 430, an electrolyte layer 440 and a cathode layer 450. There may also be (not shown) current collectors for the anode and/or cathode, a protective coating over the entire stack, and electrical contacts for the anode and cathode.

Although FIG. 2 shows a chamber configuration with horizontal planar target and substrate, the target and substrate may be held in vertical planes—this configuration can assist in mitigating particle problems if the target itself generates particles. Furthermore, the position of the target and substrate may be switched, so that the substrate is held above the target. Yet furthermore, the substrate may be flexible and moved in front of the target by a reel to reel system, the target may be a rotating cylindrical target, the target may be non-planar, and/or the substrate may be non-planar.

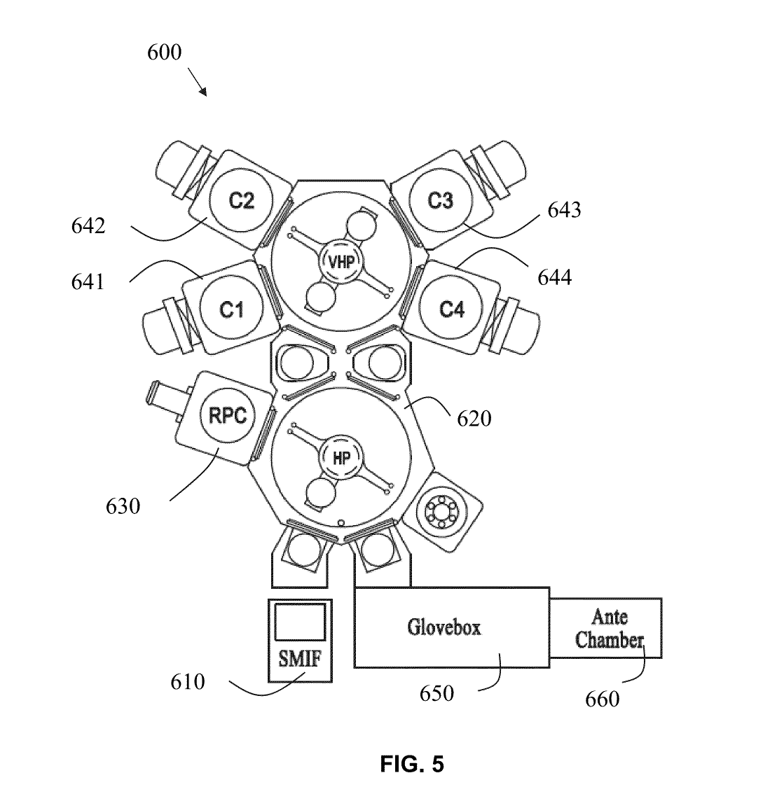

FIG. 5 is a schematic illustration of a processing system 600 for fabricating a TFB device according to some embodiments of the present disclosure. The processing system 600 includes a standard mechanical interface (SMIF) 610 to a cluster tool 620 equipped with a reactive plasma clean (RPC) chamber 630 and process chambers C1-C4 (641-644), which may be utilized in the process steps described above. A glovebox 650 may also be attached to the cluster tool if needed. The glovebox can store substrates in an inert environment (for example, under a noble gas such as He, Ne or Ar), which is useful after alkali metal/alkaline earth metal deposition. An ante chamber 660 to the glovebox may also be used if needed—the ante chamber is a gas exchange chamber (inert gas to air and vice versa) which allows substrates to be transferred in and out of the glovebox without contaminating the inert environment in the glovebox. (Note that a glovebox can be replaced with a dry room ambient of sufficiently low dew point, as used by lithium foil manufacturers.) The chambers C1-C4 can be configured for process steps for manufacturing thin film battery devices which may include: deposition of a Li metal layer on a substrate, a barrier layer of Li₃PO₄ followed by nitrogen plasma treatment, and then deposition of an electrolyte layer (e.g. LiPON by RF sputtering a Li₃PO₄ target in N₂), as described above. It is to be understood that while a cluster arrangement has been shown for the processing system 600, a linear system may be utilized in which the processing chambers are arranged in a line without a transfer chamber so that the substrate continuously moves from one chamber to the next chamber.

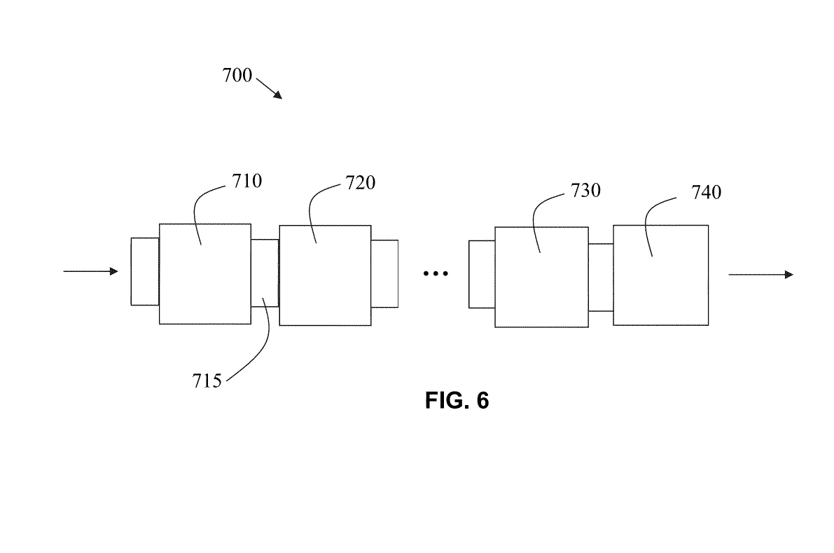

FIG. 6 shows a representation of an in-line fabrication system 700 with multiple in-line tools 710, 720, 730, 740, etc., according to some embodiments of the present disclosure. In-line tools may include tools for depositing all the layers of an electrochemical device—including TFBs, for example. Furthermore, the in-line tools may include pre- and post-conditioning chambers. For example, tool 710 may be a pump down chamber for establishing a vacuum prior to the substrate moving through a vacuum airlock 715 into a deposition tool 720. Some or all of the in-line tools may be vacuum tools separated by vacuum airlocks 715. Note that the order of process tools and specific process tools in the process line will be determined by the particular electrochemical device fabrication method being used. For example, one or more of the in-line tools may be dedicated to depositing a buffer layer on the Li metal, including a nitrogen plasma treatment for improvement of the ionic conductivity, according to some embodiments of the present disclosure, as described above. Furthermore, substrates may be moved through the in-line fabrication system oriented either horizontally or vertically. Yet furthermore, the in-line system may be adapted for reel-to-reel processing of a web substrate.

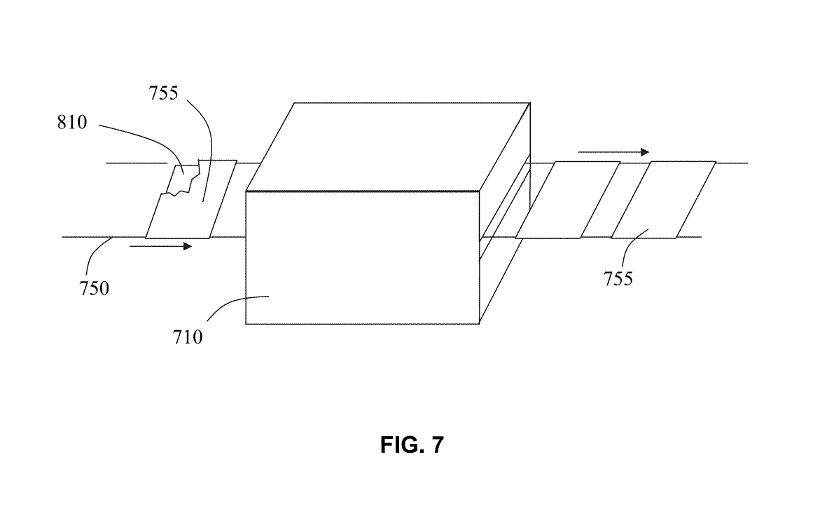

In order to illustrate the movement of a substrate through an in-line fabrication system such as shown in FIG. 6, in FIG. 7 a substrate conveyer 750 is shown with only one in-line tool 710 in place. A substrate holder 755 containing a substrate 810 (the substrate holder is shown partially cut-away so that the substrate can be seen) is mounted on the conveyer 750, or equivalent device, for moving the holder and substrate through the in-line tool 710, as indicated. A suitable in-line platform for processing tool 710 with vertical substrate configuration is Applied Materials' New Aristo™. A suitable in-line platform for processing tool 710 with horizontal substrate configuration is Applied Materials' Aton™. Furthermore, an in-line process can be implemented on a reel-to-reel system, such as Applied Materials' SmartWeb™.

An apparatus for fabricating an electrochemical device comprising a lithium metal electrode according to embodiments of the present disclosure may comprise: a first system for depositing a first layer of dielectric material on a lithium metal electrode on a substrate, the depositing the first layer of dielectric material being sputtering Li₃PO₄ in an argon ambient; a second system for inducing and maintaining a nitrogen plasma over the first layer of dielectric material to provide ion bombardment of the first layer of dielectric material for incorporation of nitrogen therein; and a third system for depositing a second layer of dielectric material on the ion bombarded first layer of dielectric material, the depositing a second layer of dielectric material being sputtering Li₃PO₄ in a nitrogen-containing ambient. The first, second and third systems may be the same system. In embodiments, the second and third systems are the same system. The apparatus may be a cluster tool or an in-line tool. Furthermore, in an in-line or reel-to-reel apparatus the depositing and inducing steps may be carried out in separate, adjacent systems.

The disclosure can be used for any applications that have LiPON deposition on a lithium metal surface—for example, energy storage devices, electrochromic devices, etc.

Although the present disclosure has been particularly described with reference to certain embodiments thereof, it should be readily apparent to those of ordinary skill in the art that changes and modifications in the form and details may be made without departing from the spirit and scope of the disclosure.

What is claimed is:

1. A method of fabricating an electrochemical device comprising a lithium metal electrode, comprising:
providing a substrate with a lithium metal electrode on the surface thereof;
depositing a first layer of dielectric material on said lithium metal electrode, said depositing said first layer of dielectric material being sputtering Li₃PO₄ in an argon ambient;
after said depositing said first layer of dielectric material, inducing and maintaining a nitrogen plasma over said first layer of dielectric material to provide ion bombardment of said first layer of dielectric material for incorporation of nitrogen therein; and
after said depositing, said inducing and said maintaining, depositing a second layer of dielectric material on the ion bombarded first layer of dielectric material, said depositing said second layer of dielectric material being sputtering Li₃PO₄ in a nitrogen-containing ambient.

2. The method of claim 1, wherein said first layer of dielectric material has a thickness between 10 nm and 100 nm.

3. The method of claim 1, wherein said first layer of dielectric material has a thickness between 40 nm and 60 nm.

4. The method of claim 1, wherein said depositing a first layer of dielectric material is in a first vacuum chamber and said inducing and maintaining is in a second vacuum chamber.

5. The method of claim 1, wherein the composition of the ion bombarded first layer of dielectric material is represented by the formula LiₐPO_{b}N_{c} wherein 2.5≦a≦3.5, 3.7≦b≦4.2, and 0.05≦c≦0.3.

6. The method of claim 1, wherein said inducing and maintaining increases the lithium ion ionic conductivity of said first layer of dielectric material.

7. The method of claim 1, wherein said inducing and maintaining reduces the density of pinholes in said first layer of dielectric material.

8. The method of claim 1, wherein said substrate is heated during said inducing and maintaining.

9. The method of claim 1, wherein said depositing said second layer of dielectric material includes sputtering Li₃PO₄ in a nitrogen and argon ambient.

10. The method of claim 1, wherein said second layer of dielectric material has a composition represented by the formula LiPON.

11. An electrochemical device comprising:
a substrate with a lithium metal electrode on the surface thereof;
an ion bombarded first layer of dielectric material on said lithium metal electrode, said ion bombarded first layer of dielectric material being a layer of material formed by sputtering a Li₃PO₄ target in an argon ambient followed by plasma treatment in a nitrogen containing ambient;
a second layer of dielectric material on the ion bombarded first layer of dielectric material, said second layer of dielectric material being formed by sputtering Li₃PO₄ in a nitrogen-containing ambient;
a second electrode on said second layer of dielectric material.

12. The electrochemical device of claim 11, wherein said ion bombarded first layer of dielectric material has a composition represented by the formula LiₐPO_{b}N_{c}, wherein 2.5≦a≦3.5, 3.7≦b≦4.2, and 0.05≦c≦0.3.

13. The electrochemical device of claim 11, wherein said second layer of dielectric material has a composition represented by the formula LiPON.

14. The electrochemical device of claim 11, wherein said electrochemical device is a thin film battery.

15. An apparatus for fabricating an electrochemical device comprising a lithium metal electrode, comprising:
a first system for depositing a first layer of dielectric material on a lithium metal electrode on a substrate, said depositing said first layer of dielectric material being sputtering Li₃PO₄ in an argon ambient;
a second system for inducing and maintaining a nitrogen plasma over said first layer of dielectric material to provide ion bombardment of said first layer of dielectric material for incorporation of nitrogen therein; and
a third system for depositing a second layer of dielectric material on the ion bombarded first layer of dielectric material, said depositing said second layer of dielectric material being sputtering Li₃PO₄ in a nitrogen-containing ambient.

16. The apparatus of claim 15, wherein said second and third systems are the same system.

17. The apparatus of claim 15, wherein said apparatus is a cluster tool.

18. The apparatus of claim 15, wherein said apparatus is an in-line tool.
